(19) United States
(12) Patent Application Publication
(10) Pub. No.: US 2003/0053506 A1
(43) Pub. Date: Mar. 20, 2003

(54) High-efficiency series-connected multiple-active region lasers and optical amplifiers

(76) Inventor: Larry A. Coldren, Santa Barbara, CA (US)

Correspondence Address: GATES & COOPER LLP, HOWARD HUGHES CENTER, 6701 CENTER DRIVE WEST, SUITE 1050, LOS ANGELES, CA, 90045, US

(21) Appl. No.: 09/535,259

(22) Filed: Mar. 23, 2000

Related U.S. Application Data
(60) Provisional application No. 60/127,109, filed on Mar. 31, 1999.

(51) Int. Cl. H01L 21/00; H01S 5/00; H01S 3/08

(52) U.S. Cl. 372/50; 438/22; 372/96

(57) ABSTRACT

Bypassing the terminal current through a multiplicity of active regions contained within the same optical cavity, easily fabricated diode lasers with external differential efficiencies greater than unity are created. Such multiple-active-region lasers can enable optical links with net electrical-to-electrical signal gain as well as facilitate impedance matching at the source. These devices can also be used within tunable laser structures, vertical laser structures or other complex laser cavity structures to provide low-cost monolithic devices with unique, desirable capabilities. When the terminal current is supplied by an integrated photodetector, low-noise optical-optical signal gain can be provided in a single monolithic semiconductor component formed by a compatible materials technology.

### CROSS-REFERENCE TO RELATED APPLICATIONS

This application claims priority under 35 U.S.C. 119(e) to U.S. Provisional Patent Application No. 60/127,109, filed Mar. 31, 1999, entitled “HIGH-EFFICIENCY SERIES-CONNECTED MULTIPLE-ACTIVE REGION LASERS AND OPTICAL AMPLIFIERS,” by Larry A. Coldren, which application is incorporated by reference herein.

### STATEMENT REGARDING FEDERALLY SPONSORED RESEARCH OR DEVELOPMENT

This invention was made with Government support under Grant No. ECS9634542, awarded by the National Science Foundation. The Government has certain rights in this invention.

### BACKGROUND OF THE INVENTION

1. Field of the Invention

This invention relates generally to electronic devices, and more particularly to high-efficiency series connected multiple active region lasers and optical amplifiers.

2. Description of Related Art

Modern day usage of optical components and lasers has made communications and data transfer more efficient and more cost effective. The use of semiconductor lasers has made the fabrication and packaging of optical sources more cost effective, as well as reducing the size of the overall device.

However, the requirements for communications and data transfer systems have also increased. Optical systems used as computer interconnections on the Internet, server-to-server connections, and other long distance, high data rate systems continually drive the optical sources and amplifiers to be more efficient and produce higher power outputs.

Currently, many semiconductor sources, such as lasers, and optical amplifier systems are limited in their ability to transfer data and/or provide higher power outputs. Differential efficiencies on the order of unity gain for such devices are currently possible. However, a differential efficiency of greater than unity should be possible, and would increase the communications and data throughput capabilities of such devices.

It can be seen, then, that there is a need in the art for optical sources and amplifiers to have increased differential efficiencies. It can also be seen that there is a need in the art for semiconductor and other lasers to have higher power outputs.

### SUMMARY OF THE INVENTION

To overcome the limitations in the prior art described above, and to overcome other limitations that will become apparent upon reading and understanding the present specification, the present invention discloses a method and device for producing high efficiency laser outputs. The device comprises a first layer having a first dopant, a plurality of active layers, wherein at least one of the plurality of active layers is coupled to the first layer, wherein each layer in the plurality of active layers comprises a p-i-n structure, and a second layer having a second dopant, coupled to at least one of the plurality of active layers, wherein when an electrical current passes from the first layer to the second layer through at least one of the plurality of active layers, a laser light output from the plurality of active lasers is produced therein.

The method comprises growing a first layer having a first dopant, growing a plurality of active layers, wherein at least one of the plurality of active layers is coupled to the first layer, wherein each layer in the plurality of active layers comprises a p-i-n structure, and growing a second layer having a second dopant, coupled to at least one of the plurality of active layers, wherein when an electrical current passes from the first layer to the second layer through at least one of the plurality of active layers, a laser light output from the plurality of active layers is produced therein.

An object of the present invention is to provide optical sources and amplifiers that have increased differential efficiencies. Another object of the present invention is to provide semiconductor and other lasers that have higher power outputs. Another object of the present invention is to provide lasers and amplifiers with improved signal-to-noise ratios.

Various advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there is illustrated and described specific examples in accordance with the invention.

### BRIEF DESCRIPTION OF THE DRAWINGS

Referring now to the drawings in which like numbers represent similar features throughout:

FIGS. 1A-1D illustrate some illustrative embodiments of devices manufactured in accordance with the present invention;

FIGS. 2A-2C illustrate the band diagrams and optical mode overlays of stacked active region devices in accordance with the present invention;

FIG. 2D illustrates a multiple-active-region vertical-cavity laser in accordance with the present invention;

FIG. 3 illustrates the light output versus the current input for various active region samples in accordance with the present invention; and

FIG. 4 is a flow chart illustrating the steps used in the present invention.

### DETAILED DESCRIPTION OF THE PREFERRED EMBODIMENT

In the following description of the preferred embodiment, reference is made to the accompanying drawings which form a part hereof, and in which is shown byway of illustration the specific embodiment in which the invention maybe practiced. It is to be understood that other embodiments may be utilized and structural and functional changes may be made without departing from the scope of the present invention.

Overview

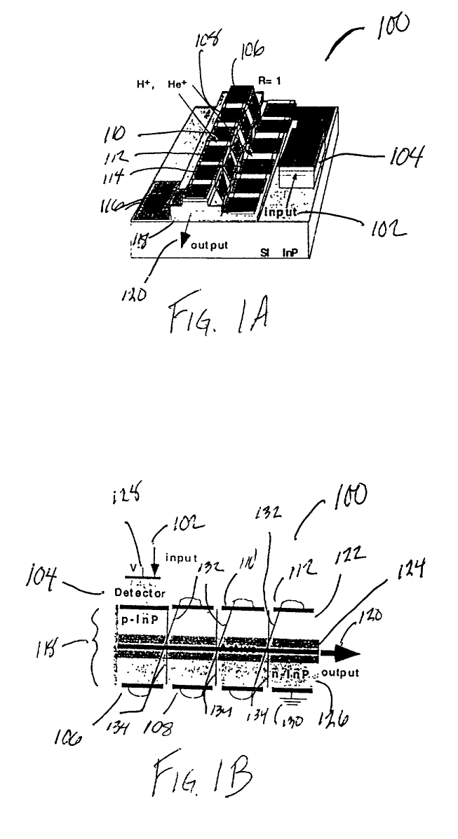

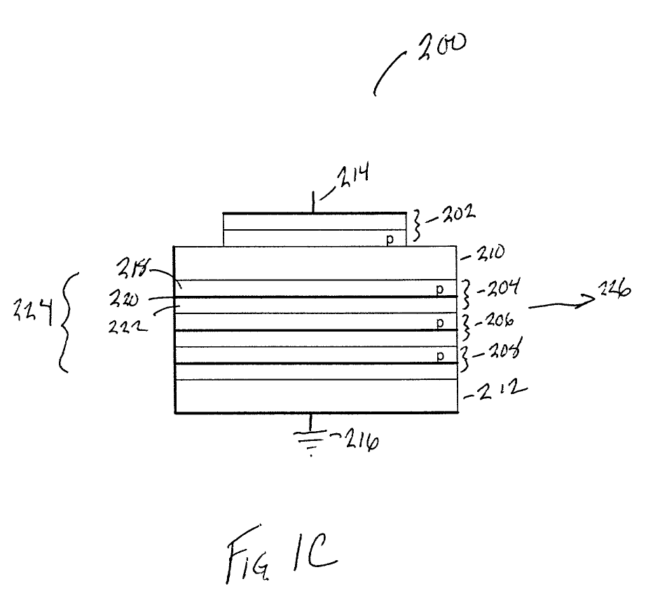

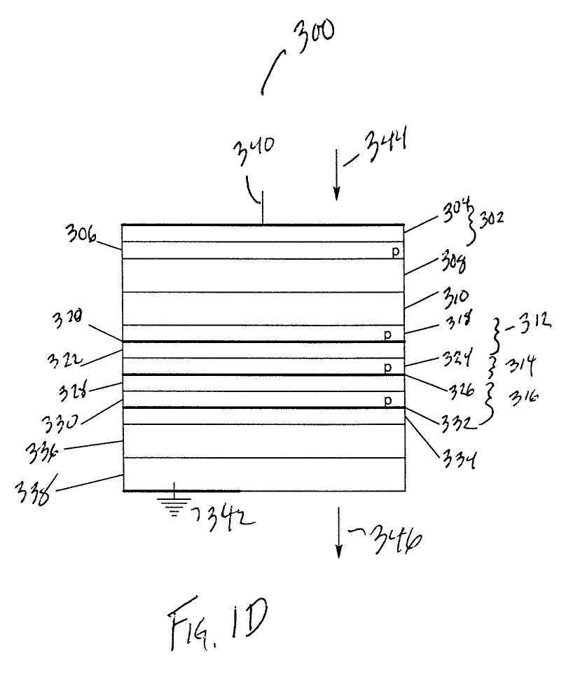

FIGS. 1A-1D illustrate some illustrative embodiments of devices manufactured in accordance with the present invention.

Semiconductor lasers with differential efficiencies greater than 1 should be possible by manufacturing lasers in accordance with FIGS. 1A-1D. FIGS. 1A and 1B show series-connected axially-segmented edge-emitting laser structures. FIG. 1C illustrates a series-connected vertically-stacked active region edge-emitting laser, and FIG. 1D illustrates a series-connected vertically-stacked active region vertical-cavity laser.

As shown in FIG. 1A, device 100 accepts input 102 to detector 104. Input 102 is typically an optical input. Detector 104 converts input 102 to an electrical signal. The electrical signal output from detector 104 is passed to an edge-emitting segment 106, which is coupled in series with edge emitting segments 108-116. For an electrical input to device 100 detector 104 is omitted and the electrical input signal is directly applied to segment 106. Each edge-emitting segment 106-116 is co-linear, e.g., each laser is manufactured in substantially the same mesa structure 118 such that each edge-emitting segment 106-116 is optically coupled to the other edge-emitting segments 106-116. However, each edge-emitting segment 106-116 is electrically separated from adjacent edge-emitting segments 106-116 by ion implantation or other isolation means.

For optical inputs to device 100 a bias voltage is placed between the top of detector 104 and the bottom of edge emitting segment 116. This bias voltage, in combination with the incident light, provides photocurrent which flows through each edge-emitting laser segment 106-116. The edge-emitting laser segments 106-116 are connected electrically in series, such that the entire terminal current passes through each edge-emitting laser segment 106-116. A DC bias current may also be applied between photodetector 104 and first laser segment 106 to pre-bias the laser to or above threshold so that all of the photocurrent is used to create additional laser output. If the input to device 100 is electrical in nature, the DC bias current and the signal current are both applied to the first laser segment 106 directly, and the photodetector 104 is not necessary.

The mesa structure 118, when provided a combined bias and signal current above the lasing threshold of the device 100, will produce a laser output 120.

In FIG. 1B, a side view of mesa structure 118 is shown. A p-doped region 122, an active region 124, and an n-doped region 126 are shown in their proper perspective. The p-doped region 122 and n-doped region 126 can be reversed without departing from the scope of the invention, e.g., regions 122 and 124 are typically of different dopant types, and are not restricted to having the p-dopant be proximate to detector 104. Although shown as indium phosphide, the doped regions 122 and 126 and active region 124 can be of any laser producing material. Bias voltage 128 and ground 130 are also shown, with connections 132 shown to connect the edge-emitting laser segments 106-116 in series. Active region 124 now contains four segments, separated by isolators 134. This segmentation produces multiple active regions 124 that are connected in series electrically and placed in a single optical cavity.

Since detector 104 is also connected in series with device 100, this allows for direct detection of an incoming optical signal in addition to applying an electrical bias or signal at the terminal beneath the detector 104. Use of the optical input 102 enables optical amplification and wavelength conversion from a single integrated element if desired.

FIG. 1B illustrates active region 124 segments that are arranged in series optically along the laser cavity within an edge-emitting geometry. The configuration of FIGS. 1A-1B allows the entire biased signal current to flow through each segment. As a result, when N segments are created, the lasing threshold for the device 100 is achieved with only 1/N of the current required for a non-segmented device 100.

Further, an increment in current above threshold (a current modulation) also results in N times the change in output 120 optical power as compared to the normal unsegmented case. In other words, the, external, differential efficiency of device 100 is multiplied by N compared to a non-segmented device of similar geometry. The spontaneous emission power at and above threshold should be approximately equal because the threshold current density and volume of the active region 124 is approximately equal. Thus, the output will increase without any noise penalty, resulting in an increase in the signal-to-noise ratio for device 100. To provide these advantages, a bias voltage 128 higher than that required for a non-segmented device 100 is required because of the increased resistance across device 100. However, the dissipated power and the thermal impedance are approximately equal to a non-segmented device 100 of similar geometry.

FIG. 1C illustrates a multiple-active region device 200. For optical signal inputs, detector 202 is connected in series with active regions 204-208, which are placed within a single edge-emitting cavity defined by layers 210 and 212. A bias voltage 214 and ground 216 are also shown.

Active region 204 is typical of the active regions 204-208, and the description of active region 204 applies equally to all active regions 204-208 of device 200. Further, a greater or lesser number of active regions 204-208 can be used in device 200 without departing from the scope of the present invention; three active regions 204-208 are shown for purposes of illustration only.

Active region 204 comprises a p-i-n structure, e.g., p-doped region 218, intrinsic region 220, and n-doped region 222. Active regions 204-208 are connected in series within a single laser cavity that emits output 226 from an edge of the laser cavity 224. Each active region comprises multiple quantum wells (MQW) that provide the laser output 226. The connection between the various p-i-n active regions generally requires a highly-doped n+-p+“back” or “tunnel” diode. In other words, the layer structure becomes a structure of the form p-i-n-n⁺-p⁺-p-i-n-n⁺-p⁺- . . . etc. for stacking two p-i-n active regions in series. By designing the optical mode of the device 200, the back diodes can be placed at optical nulls of the device 200, which reduces or eliminates the optical interference caused by the back diode highly-doped regions within the laser cavity of the edge-emitter structure.

The stacking of multiple active regions 204-208 results in a multiplication of the differential efficiency by the number of active regions, e.g., for three active regions 204-208, the differential efficiency will be multiplied by three, provided the process does not result in additional optical loss or non-radiative carrier recombination. The incorporation of highly doped regions to create the series connections may add such deleterious effects, but these effects can be reduced to substantially insignificant amounts using common fabrication practices. The threshold current to activate the multiple active regions 204-208 decreases depending on the bias point of the device 200. Therefore, the spontaneous emission at and above the threshold current point would increase by less than the number of multiple active regions 204-208, which increases the signal to noise ratio at higher bias voltages. Device 200 is a higher-voltage, higher impedance (due to the multiple stacked active regions 204-208 series resistances), with a higher heat generation density, but is easy to fabricate and the large optical cavity 224 provides better coupling to optical fibers. The integration of detector 202 provides efficient, low-noise, and inexpensive analog repeaters, wavelength converters, and optical taps.

FIG. 1D illustrates a vertical cavity laser fabricated in accordance with the present invention.

Device 300 comprises detector 302, which comprises n-doped region 304 and p doped region 306, and is coupled to a differential Bragg reflector (DBR) mirror stack 308. Again, for an electrical input signal the detector stage is omitted. The mirror is grown or otherwise coupled to the p-doped gain material 310. Again, active regions 312-316 are stacked in series in the cavity of the laser, where active region 312 comprises p-doped region 318, intrinsic region 320, and n-doped region 322, active region 314 comprises p-doped region 324, intrinsic region 326, and n-doped region 328, and active region 316 comprises p-doped region 330, intrinsic region 332, and n-doped region 334, respectively. The active regions 312-316 are connected serially, and are then connected to n-doped gain material 336. Material 336 is coupled to the other DBR mirror stack 338. Bias voltage 340 and ground 342 are applied to device 300. Input 344 is applied, and laser output 346 emits from the stack opposite from input 344.

Again, active regions 312-316 comprise p-i-n structures, e.g., p-doped region 318, intrinsic region 320, and n-doped region 322. Active regions 312-316 are connected in series within a single laser cavity that emits output 346. Each active region comprises multiple quantum wells (MQW) that provide the laser output 346. As in the edge-emitter case, tunnel or back diodes are incorporated between the p-i-n multiple active regions for low voltage cascading. However, in the vertical-cavity laser case, these highly-doped regions can be placed at optical standing-wave electric-field nulls, such that little optical loss is added to the overall structure.

The stacking of multiple active regions 312-316 results in a multiplication of the differential efficiency by the number of active regions, e.g., for three active regions 312-316, the differential efficiency will be multiplied by three. The threshold current to activate the multiple active regions 312-316 decreases depending on the bias point of the device 300. Therefore, the spontaneous emission at and above the threshold current point would increase by less than the number of multiple active regions 312-316, which increases the signal to noise ratio at higher bias voltages.

The basic characteristics of the configurations of FIGS. 1A-1D can be understood by deriving the output power vs. input current starting from a set of phenomenological rate equations. Of course, the result does not illustrate the effects of correlated spontaneous emission noise, but it does contain the inherent increase in differential efficiency, reduction in threshold current, and value of spontaneous emission, which clamps at threshold due to carrier clamping.

The carrier and photon density rate equations maybe written as:

$$\frac{ⅆ N}{ⅆ t} = \frac{{η}_{i} I}{q {V}_{A}} - \frac{N}{τ} - g {V}_{g} {N}_{P}$$

$$\frac{ⅆ {N}_{P}}{ⅆ t} = Γ g {v}_{g} {N}_{p} + {Γβ}_{s p} {R}_{s p} - \frac{{N}_{p}}{{τ}_{p}}$$

where

N=carrier density

N_{P}=photon density

ηᵢ=internal efficiency

I=input current that flows through each active region

V=volume of each of the N_{A} active regions,

τ=carrier lifetime in the absence of stimulated emission,

v_{g}=group velocity,

g=incremental plane-wave gain of the active material,

Γ=confinement factor including all active regions (Γ=Γ_{A}N_{A}, where Γ_{A}=V_{A}/V_{P} is the overlap of one active region with the optical mode),

β_{SP}=spontaneous emission factor, and

τ_{P}=photon lifetime.

The output power above threshold is given by:

$${P}_{0} = {η}_{i} {N}_{A} ( \frac{{α}_{m}}{⟨ {α}_{i} ⟩ + {α}_{m}} ) \frac{h v}{q} ( I - {I}_{t h} ) fo r I > {I}_{t h}$$

where

<αi>=average internal loss

αaₘ=mirror loss =(1/L)ln(1/R)

R=mean mirror power reflectivity

I=input current, and

Iₜₕ=threshold current

This is identical to the output power of a single active region, except the differential efficiency is now given by:

$${η}_{d} = {N}_{A} ( \frac{{η}_{i} {α}_{m}}{⟨ {α}_{i} ⟩ + {α}_{m}} )$$

which is N_{A} times larger than the single active region differential efficiency.

Using an exponential gain model for the current density (J), the threshold current maybe written as:

$${I}_{t h} = [ \frac{A {J}_{t r}}{{η}_{i}} ] exp ( \frac{{g}_{t h}}{{g}_{0}} )$$

where

gₜₕ=[<αᵢ>+αₘ]/Γ

Jₜᵣ=transparent current density, and

A=area of each active region.

In the device of FIGS. 1A-1B, the area A is reduced to 1/N_{A}, so the threshold current is seen to reduce by the same amount, if the active volume, Γ, and losses remain the same. In practical situations, however, there may be some slight decreases in A and Γ, as well as some increases in average internal loss, which would increase the threshold slightly.

In the devices of FIGS. 1C-1D, Γ is approximately N_{A} times larger than a device with one active region if the optical mode remains the same, gₜₕ is reduced by a factor of N_{A} and I^{th} is also reduced by a factor of N_{A}. The average internal loss may also increase in the process of adding additional active regions, so the overall increase in differential efficiency may be increased slightly less than N_{A}.

Below the threshold current the output power is given by the spontaneous emission power

$${P}_{0} ( I < {I}_{t h} ) = {η}_{r} {η}_{i} {N}_{A} ( \frac{{α}_{m}}{⟨ {α}_{i} ⟩ + {α}_{m}} ) \frac{h v}{q} {β}_{s p} I$$

Thus, for a given current the spontaneous emission is N_{A} times larger. However, according to the exponential gain model equations above, the threshold current is reduced by some amount (up to N_{A} times). Therefore, at and above threshold, the spontaneous emission power may be only slightly larger than with one active region. Since the differential efficiency is N_{A} times larger, the ratio of stimulated-to-spontaneous emission will be increased, except very close to threshold.

Using the present invention with different mirror reflectivities, cavity lengths, and/or confinement factors per active region in going from a single to a multiple-active-region design may also increase the differential efficiency of devices made in accordance with the present invention. The conclusions made above assume that the mirror loss and confinement factor for each active region are the same in both single active region and multiple-active region cases. In fact, it is possible to further improve the desired characteristics by changing these parameters in an optimized multiple-active-region design using the above-provided equations.

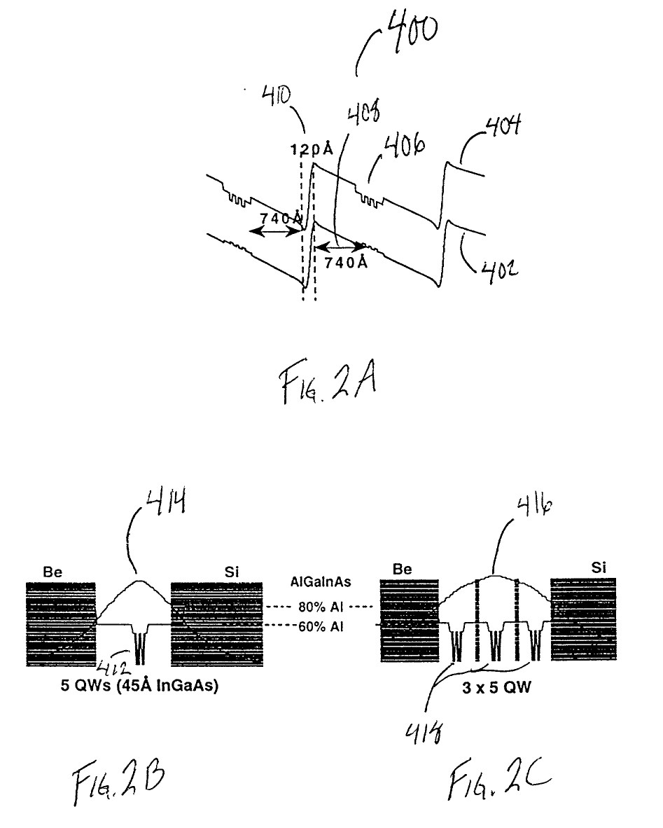

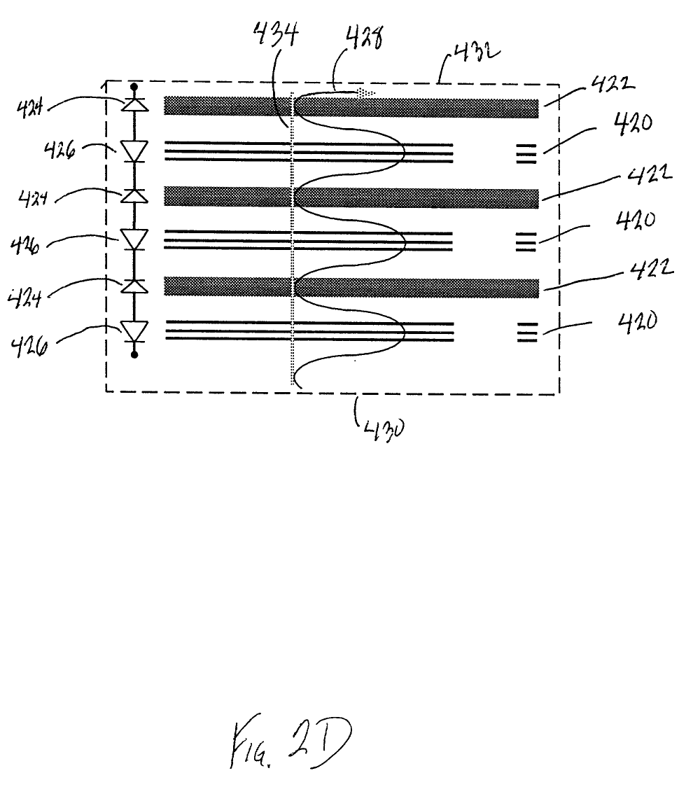

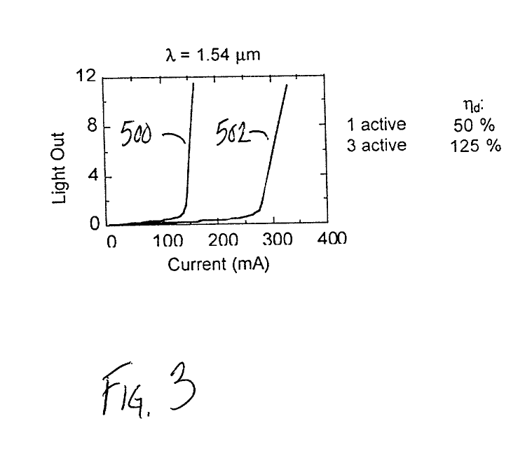

FIGS. 2A-2C illustrate a band diagram and optical mode overlays derived from experimental results for single and multiple-active-region edge-emitting devices.

FIG. 2A illustrates the band diagram 400 for a two-active region stack. For this illustration, the valence band 402 and conduction band 404 are shown, with the MQW region 406 illustrated. The distance 408 from the MQW region 406 to the edge of the active region is 740 angstroms. The tunnel-diode 410 between active regions is 120 angstroms thick.

FIG. 2B illustrates a single active layer 406 comprising 5 quantum wells in a 45 angstrom indium gallium arsenide (InGaAs) stack The optical mode 414 is indicated. FIG. 2C illustrates the optical mode 416 for a three active-region device, where each active region comprises a five quantum well layer 418.

FIG. 2D illustrates a multiple-active-region vertical-cavity laser in accordance with the present invention.

Active regions 420, consisting of single Quantum Wells (QWs) or MQWs are shown. Back (or tunnel) diodes 422 are shown between the active regions 420, and connect the active regions 420 together. Schematically, the back diodes 422 are shown as diodes 424, and active regions 420 are shown as diodes 426. Optical path 428 is shown, and DBR mirror stacks are located at positions 430 and 432. Note that the back diodes 422 are located at nulls of the standing wave 428, which reduces or eliminates interference between the back diodes 422 and the standing wave 428. Zero reference line 434 illustrates the zero of the electric field squared, and illustrates that the back diodes are located at nulls of the electric field.

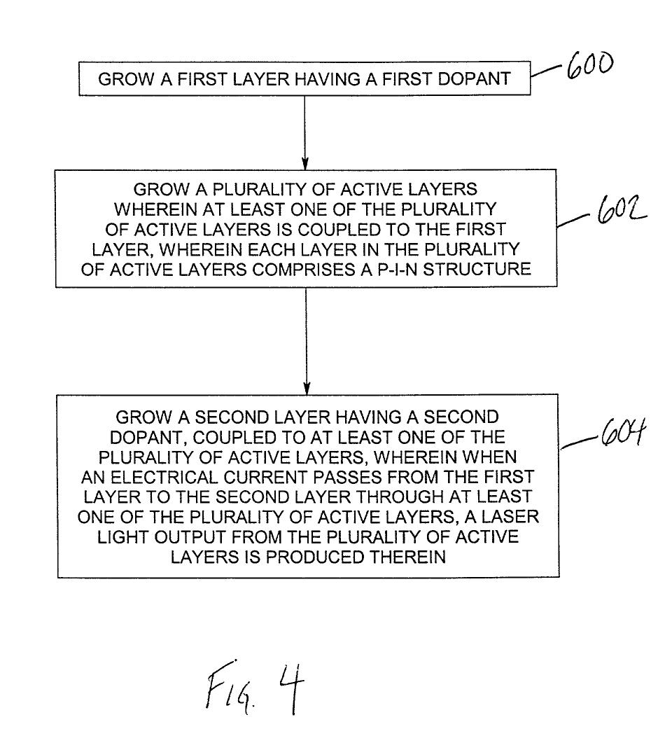

FIG. 3 illustrates the light output versus current input for a single active layer device and a multiple active layer device in accordance with the present invention.

Graph 500 illustrates the light output for a single active layer device. The differential efficiency is 50 percent for such a device.

Graph 502 illustrates the light output for a multiple, three-active layer device. Note that the differential efficiency is now 125 percent, or greater than unity (1.25).

Logic

FIG. 4 is a flow chart illustrating the steps used in the present invention.

Block 600 represents performing the step of growing a first layer having a first dopant;

Block 602 represents performing the step of growing a plurality of active layers, wherein at least one of the plurality of active layers is coupled to the first layer, wherein each layer in the plurality of active layers comprises a p-i-n structure.

Block 604 represents performing the step of growing a second layer having a second dopant, coupled to at least one of the plurality of active layers, wherein when an electrical current passes from the first layer to the second layer through at least one of the plurality of active layers, a laser light output from the plurality of active layers is produced therein.

Conclusion

In summary, the present invention provides a method and device for producing high differential efficiency laser outputs. The device comprises a first layer having a first dopant, a plurality of active layers, wherein at least one of the plurality of active layers is coupled to the first layer, wherein each layer in the plurality of active layers comprises a p-i-n structure, and a second layer having a second dopant, coupled to at least one of the plurality of active layers, wherein when an electrical current passes from the first layer to the second layer through at least one of the plurality of active layers, a laser light output from the plurality of active lasers is produced therein.

The method comprises growing a first layer having a first dopant, growing a plurality of active layers, wherein at least one of the plurality of active layers is coupled to the first layer, wherein each layer in the plurality of active layers comprises a p-i-n structure, and growing a second layer having a second dopant, coupled to at least one of the plurality of active layers, wherein when an electrical current passes from the first layer to the second layer through at least one of the plurality of active layers, a laser light output from the plurality of active layers is produced therein.

Within the scope of the present invention, other embodiments or alterations of the descriptions herein are possible with the present invention. For example, the present invention is described with respect to certain materials families, e.g., indium phosphide (InP), indium gallium arsenide (InGaAs), and other materials. However, many semiconductor and other materials, such as indium aluminum gallium arsenide, aluminum gallium indium arsenide, indium arsenide, indium antimonide, gallium nitride, and other III-V, II-V, tertiary and quaternary materials may be used without departing from the scope of the present invention. Further, the detector that is described as monolithic with the laser cavity can be a separate device if desired. The device of the present invention, although typically described as a three active-layer device, can be a multiple active layer device of any number, e.g., a five active-layer device, a seven active-layer device, a ten active-layer device, etc., without departing from the scope of the present invention.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A semiconductor device, comprising:
a first layer having a first dopant;
a plurality of active layers, wherein at least one of the plurality of active layers is coupled to the first layer, wherein each layer in the plurality of active layers comprises a p-i-n structure; and
a second layer having a second dopant, coupled to at least one of the plurality of active layers, wherein when an electrical current passes from the first layer to the second layer through at least one of the plurality of active layers, a laser light output from the plurality of active lasers is produced therein.

2. The semiconductor device of claim 1, further comprising a detector, coupled to the first layer, the detector providing the electrical current to the first layer.

3. The semiconductor device of claim 1, wherein the first layer is coupled to more than one of the plurality of the active layers, the second layer is coupled to more than one of the plurality of active layers, and the current passes through the active layers and the first and second layers in a serial fashion.

4. The semiconductor device of claim 3, further comprising a plurality of back diodes coupled between each of the plurality of active layers.

5. The semiconductor device of claim 4, wherein the back diodes are located at optical nulls within the semiconductor device.

6. The semiconductor device of claim 1, wherein at least one of the plurality of active layers comprises a multiple quantum well structure.

7. The semiconductor device of claim 1, wherein the first layer is coupled to only one of the plurality of active layers, the second layer is coupled to a different one of the plurality of active layers, and the plurality of active layers are stacked serially, such that the current passes through the first layer before passing through the active layers.

8. The semiconductor device of claim 7, wherein the laser output is from an edge of the semiconductor device.

9. The semiconductor device of claim 7, further comprising a detector, coupled to the first layer, for providing the current that passes through the semiconductor device.

10. The semiconductor device of claim 7, further comprising a first mirror, coupled to the first layer, and a second mirror, coupled to the second layer, wherein when the current passes through the plurality of active layers, the laser output is substantially from a plane perpendicular to a plane of the active layers.

11. The semiconductor device of claim 10, further comprising at least one back diode, wherein a back diode is coupled between each pair of active layers and a back diode is coupled between the first layer and the first mirror.

12. The semiconductor device of claim 11, wherein the back diodes are located at optical nulls of the semiconductor device.

13. A method for making a semiconductor device, comprising:
growing a first layer having a first dopant;
growing a plurality of active layers, wherein at least one of the plurality of active layers is coupled to the first layer, wherein each layer in the plurality of active layers comprises a p-i-n structure; and
growing a second layer having a second dopant, coupled to at least one of the plurality of active layers, wherein when an electrical current passes from the first layer to the second layer through at least one of the plurality of active layers, a laser light output from the plurality of active lasers is produced therein.

14. The method of claim 13, further comprising growing a detector, coupled to the first layer, the detector providing the electrical current to the first layer.

15. The method of claim 13, wherein the first layer is coupled to more than one of the plurality of the active layers, the second layer is coupled to more than one of the plurality of active layers, and the current passes through the active layers and the first and second layers in a serial fashion.

16. The method of claim 13, wherein at least one of the plurality of active layers comprises a multiple quantum well structure.

17. The method of claim 13, wherein the first layer is coupled to only one of the plurality of active layers, the second layer is coupled to a different one of the plurality of active layers, and the plurality of active layers are stacked serially, such that the current passes through the first layer before passing through the active layers.

18. The method of claim 17, wherein the laser output is from an edge of the semiconductor device.

19. The method of claim 18, further comprising growing at least one back diode between each of the plurality of active layers.

20. The method of claim 19, wherein the back diodes are located at optical nulls within the semiconductor device.

21. The method of claim 17, further comprising growing a detector, coupled to the first layer, for providing the current that passes through the semiconductor device.

22. The method of claim 17, further comprising growing a first mirror, coupled to the first layer, and growing a second mirror, coupled to the second layer, wherein when the current passes through the plurality of active layers, the laser output is substantially from a plane perpendicular to a plane of the active layers.

23. The method of claim 21, further comprising growing at least one back diode between each pair of active layers and growing a back diode between the first layer and the first mirror.

24. The method of claim 23, wherein the back diodes are located at optical nulls of the semiconductor device.

25. A laser output, produced by a device manufactured by the steps comprising:
growing a first layer having a first dopant;
growing a plurality of active layers, wherein at least one of the plurality of active layers is coupled to the first layer, wherein each layer in the plurality of active layers comprises a p-i-n structure; and
growing a second layer having a second dopant, coupled to at least one of the plurality of active layers, wherein when an electrical current passes from the first layer to the second layer through at least one of the plurality of active layers, the laser output from the plurality of active lasers is produced therein.
